(19) United States
(12) Patent Application Publication
(10) Pub. No.: US 2022/0020638 A1
(43) Pub. Date: Jan. 20, 2022

(54) Interconnect Structures with Selective Barrier for BEOL Applications

(71) Applicant: International Business Machines Corporation, Armonk, NY (US)

(72) Inventors: Prasad Bhosale, Albany, NY (US); Rudy J. Wojtecki, San Jose, CA (US); Nicholas Anthony Lanzillo, Wynantskill, NY (US); Chih-Chao Yang, Glenmont, NY (US)

(21) Appl. No.: 16/932,193

(22) Filed: Jul. 17, 2020

(51) Int. Cl. H01L 21/768; H01L 23/532

(52) U.S. Cl. CPC H01L 21/76844; H01L 23/53238; H01L 21/7685; H01L 23/53209; H01L 21/76834; H01L 23/53266

(57) ABSTRACT

Interconnect structures with selective barrier for back-end-of-line (BEOL) applications are provided. In one aspect, an interconnect structure includes: a dielectric disposed over at least one metal line; at least one feature present in the dielectric over the at least one metal line; a barrier layer lining only surfaces of the dielectric within the at least one feature; at least one interconnect present in the at least one feature over the barrier layer, wherein the at least one interconnect is in direct contact with the at least one feature. A method of forming an interconnect structure is also provided.

### FIELD OF THE INVENTION

The present invention relates to interconnect structures, and more particularly, to interconnect structures with selective barrier for back-end-of-line (BEOL) applications.

### BACKGROUND OF THE INVENTION

So called ‘damascene’ or ‘dual damascene’ processes are often employed to form interconnect structures such as metal lines and/or conductive vias in semiconductor device back-end-of-line (BEOL) levels. With these processes, a feature (damascene process) or a combination of features (dual damascene process) such as a trench and/or a via are patterned in a dielectric. The features are then filled with a metal or combination of metals. Prior to filling metal into the features, the respective trenches and/or vias are first lined with a barrier layer.

However, the presence of the barrier layer at the bottom of the features increases the resistance of the interconnect structure. High via resistance is one of the major performance limitations at the BEOL metal level, especially those where line run lengths are relatively small.

Therefore, improved BEOL interconnect structures and techniques for formation thereof which reduce the via resistance would be desirable.

### SUMMARY OF THE INVENTION

The present invention provides interconnect structures with selective barrier for back-end-of-line (BEOL) applications. In one aspect of the invention, an interconnect structure is provided. The interconnect structure includes: a dielectric disposed over at least one metal line; at least one feature present in the dielectric over the at least one metal line; a barrier layer lining only surfaces of the dielectric within the at least one feature; at least one interconnect present in the at least one feature over the barrier layer, wherein the at least one interconnect is in direct contact with the at least one feature.

In another aspect of the invention, a structure is provided. The structure includes: a dielectric disposed over at least one metal line; at least one feature present in the dielectric over the at least one metal line; a self-assembled monolayer (SAM) disposed only on the at least one metal line within the at least one feature; and a barrier layer lining only surfaces of the dielectric within the at least one feature.

In yet another aspect of the invention, a method of forming an interconnect structure is provided. The method includes: depositing a dielectric over at least one metal line; patterning at least one feature in the dielectric over the at least one metal line; selectively forming a SAM only on the at least one metal line within the at least one feature; curing the SAM to cross-link the SAM; depositing a barrier layer into and lining the at least one feature, wherein the SAM suppresses deposition of the barrier layer onto the at least one metal line such that the barrier layer as-deposited is present only on surfaces of the dielectric within the at least one feature; removing the SAM; and depositing at least one metal into the at least one feature over the barrier layer to form at least one interconnect in the at least one feature that is in direct contact with the at least one feature.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for forming a bottom barrier-less interconnect according to an embodiment of the present invention;

FIG. 2 is a cross-sectional diagram illustrating an exemplary structure having metal lines according to an embodiment of the present invention;

FIG. 3 is a cross-sectional diagram illustrating a dielectric having been deposited over the metal lines according to an embodiment of the present invention;

FIG. 4 is a cross-sectional diagram illustrating features having been patterned in the dielectric, one or more of which is located over the metal lines according to an embodiment of the present invention;

FIG. 5 is a cross-sectional diagram illustrating a self-assembled material (SAM) having been selectively formed on the surfaces of the metal lines exposed within the features according to an embodiment of the present invention;

FIG. 6 is a cross-sectional diagram illustrating the SAM having been cured according to an embodiment of the present invention;

FIG. 7 is a cross-sectional diagram illustrating a barrier layer having been deposited into and lining the features, whereby the SAM suppresses deposition of the barrier layer onto the metal lines at the bottoms of the features such that the barrier layer is present only along the surfaces of the dielectric according to an embodiment of the present invention;

FIG. 8 is a cross-sectional diagram illustrating the SAM having been removed from the surface of the metal lines within the features according to an embodiment of the present invention;

FIG. 9 is a cross-sectional diagram illustrating a metal(s) having been deposited into the features over the barrier layer to form interconnects in the features according to an embodiment of the present invention;

FIG. 10 is a cross-sectional diagram illustrating a capping layer having been formed on the dielectric over the interconnects according to an embodiment of the present invention;

FIG. 11 is a diagram illustrating an exemplary reaction to functionalize the SAM for preferential binding to metal surfaces according to an embodiment of the present invention; and

FIG. 12 is a diagram illustrating an SAM of a photoactive polymer selectively deposited onto the metal lines having been cross-linked by exposure to UV light according to an embodiment of the present invention.

### DETAILED DESCRIPTION OF PREFERRED EMBODIMENTS

As provided above, high via resistance is a major performance limitation in the back-end-of-line (BEOL) interconnect structures. This high via resistance can be attributed, at least in part, to the barrier layer that lines the interconnects and which, with conventional interconnect designs, is present at the bottom of the interconnects.

Advantageously, it has been found herein that bottom barrier-less via interconnects can be formed using selective deposition of atomic layer deposition (ALD) barrier films. Through this process, the barrier layer is formed only along the via sidewalls and not at the via bottom. As such, the interconnect resistance is reduced, leading to performance increases of up to about 6%. As will be described in detail below, the selective barrier layer deposition leverages formation of a self-assembled monolayer (SAM) on the metal surfaces at the bottom of the via to prevent formation of the barrier layer material on those metal surfaces. As a result, the barrier layer material is deposited only on the surrounding dielectric.

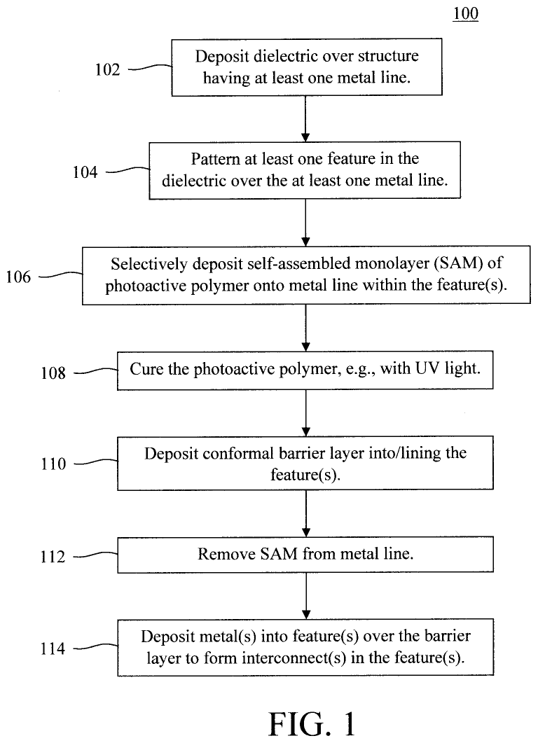

An overview of the present techniques for forming a bottom barrier-less interconnect is now provided by way of reference to methodology 100 of FIG. 1. In step 102, a dielectric is deposited over a structure having at least one metal line. This structure will be described in further detail below.

Suitable dielectric materials include, but are not limited to, oxide low-κ materials such as silicon oxide (SiOx) and/or oxide ultralow-κ interlayer dielectric (ULK-ILD) materials, e.g., having a dielectric constant κ of less than 2.7. By comparison, silicon dioxide (SiO₂) has a dielectric constant κ value of 3.9. Suitable ultralow-κ dielectric materials include, but are not limited to, porous organosilicate glass (pSiCOH). A process such as chemical vapor deposition (CVD), atomic layer deposition (ALD), or physical vapor deposition (PVD) can be used to deposit the dielectric, after which the dielectric can be planarized using a process such as chemical mechanical polishing (CMP).

In step 104, at least one feature is patterned in the dielectric over metal line(s). As highlighted above, a so called ‘damascene’ or ‘dual damascene’ process involves the patterning of a feature such as a trench or via (damascene) or combination of features such as a trench aligned over a via (dual damascene), and then filling of the feature with a contact metal or combination of metals. In the case of a dual damascene process, the trench can be patterned before the via, or vice versa. When the trench is patterned before the via, it is also referred to as a ‘trench-first’ process. Alternatively, when the via is patterned before the trench, it is referred to as a ‘via-first’ process.

The feature(s) patterned in the dielectric extend down to the metal line(s). To look at it another way, the metal line(s) is exposed at the bottom of the feature(s). As highlighted above, the feature(s) can include trenches, vias, and combinations thereof. Standard lithography and etching techniques can be employed to pattern the feature(s) in the dielectric. With standard lithography and etching processes, a lithographic stack, e.g., photoresist/organic planarizing layer (OPL)/anti-reflective coating (ARC), is used to pattern a hardmask with the footprint and location of feature(s). Suitable hardmask materials include, but are not limited to, nitride hardmask materials such as silicon nitride (SiN), silicon oxynitride (SiON), silicon carbide nitride (SiCN), and/or oxide hardmask materials such as silicon oxide (SiOx). Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP). An etch is then used to transfer the pattern from the hardmask to the underlying dielectric. A directional (anisotropic) etching process such as reactive ion etching (RIE) can be employed for the etch.

In order to form a bottom barrier-less interconnect, the barrier layer that will be deposited into and lining the feature(s) (see below) needs to be selectively absent from the bottom of the features. To look at it another way, that barrier layer will only be deposited onto the dielectric surfaces within the feature(s), i.e., the barrier layer will not be deposited onto the metal line(s) exposed at the bottom(s) of the feature(s). Such a configuration will beneficially provide direct metal-to-metal contact between the interconnect(s) that will be formed in the feature(s) (see below) and the metal line(s).

Advantageously, it has been found herein that the selective formation of self-assembled monolayer (SAM) of a photoactive polymer on the metal line(s) can be used to prevent deposition of barrier layer on the exposed surface(s) of the metal line(s) at the bottoms of the feature(s). According to an exemplary embodiment, the photoactive SAM is a dyine-reinforced polymer such as polynorbornene (PNB) that is configured for preferential deposition onto metal surfaces as opposed to dielectric surfaces.

Thus, in step 106, a SAM of the photoactive polymer is selectively formed on the exposed surface(s) of the metal line(s) within the feature(s). According to an exemplary embodiment, the photoactive polymer is dissolved in a solvent such as 0.1 weight percent (wt. %) 4-methyl-2-pentanol forming a solution. The device sample is then immersed in the solution for a duration of from about 5 minutes to about 20 minutes and ranges therebetween, e.g., for about 10 minutes. The device sample is then removed from the solution and rinsed. Following the rinse, a SAM of the photoactive polymer will be formed on the exposed surface(s) of the metal line(s) within the feature(s), and none of the photoactive polymer will remain on the dielectric surfaces within the feature(s).

In step 108, the SAM of the photoactive polymer on the exposed surface(s) of the metal line(s) within the feature(s) is cured. According to an exemplary embodiment, this curing is performed by exposing the photoactive polymer to ultraviolet (UV) light. Exposing the photoactive polymer to UV light serves to cross-link the polymer. The (cured) SAM modifies the surface energy properties of the metal line(s) to which the SAM is grafted, thereby suppressing chemical deposition of the barrier layer material that is next deposited into the feature(s).

Namely, in step 110 a conformal barrier layer is deposited into and lining the feature(s). Advantageously, due to the presence of the SAM on the metal line(s) at the bottom of the feature(s), deposition of the barrier layer onto the metal line(s) within the feature(s) is suppressed. As such, the as-deposited barrier layer will be present along the dielectric surfaces and not at the bottom(s) of the feature(s). Suitable barrier layer materials include, but are not limited to, tantalum nitride (TaN), titanium nitride (TiN), titanium oxide (TiOx) and/or tungsten carbide (WC). A conformal deposition process such as ALD or PVD can be employed to deposit the barrier layer into and lining the feature(s). For instance, according to an exemplary embodiment, a thermal ALD process at a temperature of from about 250° C. to about 300° C. and ranges therebetween is employed to deposit the barrier layer into the feature(s). In one exemplary embodiment, the barrier layer has a thickness of from about 2 nanometers (nm) to about 5 nm and ranges therebetween. Additionally, a seed layer can be deposited into and lining the feature(s) prior to metal deposition. A seed layer facilitates plating of the metal into the feature(s).

In step 112, the SAM is removed from the surface of the metal line(s) within the feature(s). An etch process such as RIE or a wet chemical etch can be employed to remove the SAM from the feature(s). Advantageously, following removal of the SAM the surface of the metal line(s) within the feature(s) are now exposed, which will enable the interconnect(s) that will be formed in the feature(s) to be in direct contact with the metal line(s). Namely, as highlighted above, there is no barrier layer present at the bottom(s) of the feature(s). The absence of a barrier layer at the bottom(s) of the features vastly reduces the resistance of the interconnect structure.

In step 114, metal or combination of metals is then deposited into the feature(s) over the barrier layer forming an interconnect(s) in the feature(s). However, as highlighted above, due to the absence of the barrier layer at the bottom(s) of the feature(s), the interconnect will be in direct contact with the underlying metal line(s). Suitable metals include, but are not limited to, copper (Cu), tungsten (W), cobalt (Co) and/or ruthenium (Ru). A process such as evaporation, sputtering or electrochemical plating can be employed to deposit the metal(s) into the feature(s). Following deposition, the metal overburden can be removed using a process such as chemical vapor deposition (CVD).

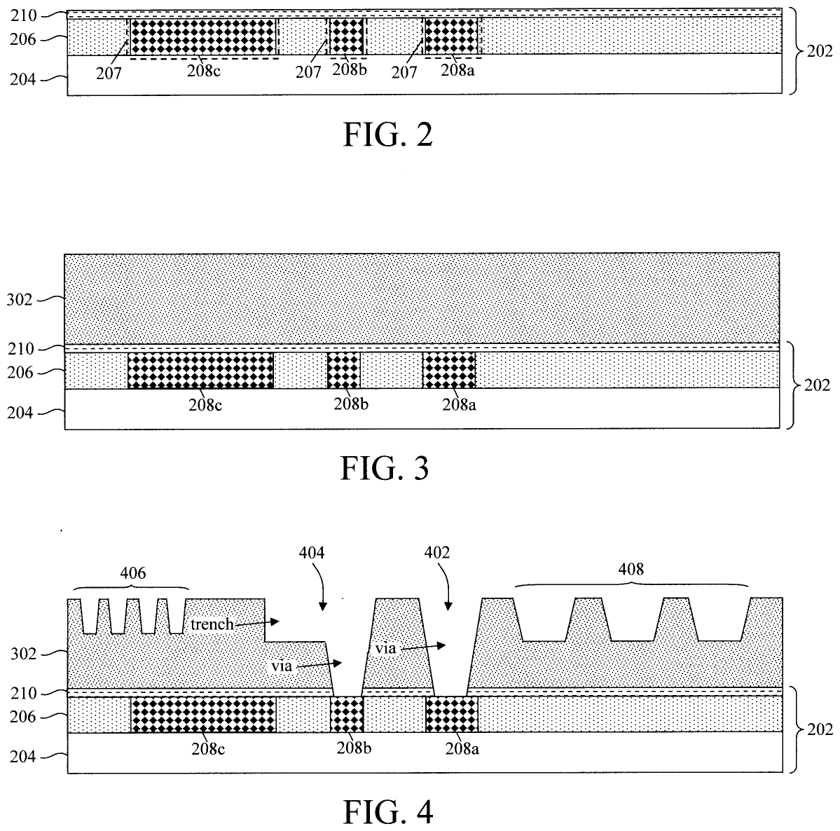

An exemplary implementation of methodology 100 for forming a bottom barrier-less interconnect is now described by way of reference to FIGS. 2-10. As shown in FIG. 2, the process begins with a structure 202 having at least one metal line 208. More specifically, in this example, structure 202 includes a substrate 204, and a dielectric 206 disposed on the substrate 204. Metal lines 208a,b,c, etc. are formed in the dielectric 206.

According to an exemplary embodiment, substrate 204 is a bulk semiconductor wafer, such as a bulk silicon (Si), bulk germanium (Ge), bulk silicon germanium (SiGe) and/or bulk III-V semiconductor wafer. Alternatively, substrate 204 can be a semiconductor-on-insulator (SOI) wafer. A SOI wafer includes a SOI layer separated from an underlying substrate by a buried insulator. When the buried insulator is an oxide it is referred to herein as a buried oxide or BOX. The SOI layer can include any suitable semiconductor, such as Si, Ge, SiGe, and/or a III-V semiconductor. Substrate 204 may already have pre-built structures (not shown) such as transistors, diodes, capacitors, resistors, interconnects, wiring, etc.

As provided above, suitable materials for dielectric 206 include, but are not limited to, oxide low-ic materials such as SiOx and/or oxide ULK-ILD materials such as pSiCOH. A process such as CVD, ALD, or PVD can be used to deposit the dielectric 206 onto substrate 204. Following deposition, dielectric 206 can be planarized using a process such as CMP. According to an exemplary embodiment, dielectric 206 has a thickness of from about 10 nm to about 30 nm and ranges therebetween.

In the present example, bottom barrier-less interconnects will be formed in contact with metal lines 204a and 204b. However, it is to be understood that this is for illustrative purposes only. Namely, the present techniques can be implemented to form bottom barrier-less interconnects to any number and/or configuration of metal lines.

Metallization techniques are employed to form metal lines 208a,b,c, etc. in dielectric 206, whereby standard lithography and etching techniques (see above) are used to pattern trenches (see dashed lines 207 in FIG. 2 depicting the outlines of the trenches) in dielectric 206. The trenches are then filled with a metal(s) to form the metal lines 208a,b,c, etc. As provided above, suitable metals include, but are not limited to, Cu, W, Co and/or Ru. The metal(s) can be deposited into the trenches using a process such as evaporation, sputtering or electrochemical plating. Following deposition, the metal overburden can be removed using a process such as CMP. As shown in FIG. 2, the CMP provides a coplanar surface across the tops of dielectric 206 and metal lines 208a,b,c, etc.

Prior to depositing the metal(s) into the trenches, a conformal barrier layer (not shown) can be deposited into and lining the trenches. Use of such a barrier layer helps to prevent diffusion of the contact metal(s) into the surrounding dielectric. As provided above, suitable barrier layer materials include, but are not limited to, TaN, TiN, TiOx and/or WC. Additionally, a seed layer (not shown) can be deposited into and lining the trenches prior to metal deposition. A seed layer facilitates plating of the metal into the trenches.

A capping layer 210 is then formed on the dielectric 206 over the metal lines 208a,b,c, etc. Capping layer 210 serves to protect the metal lines 208a,b,c, etc. during subsequent processing steps, as well as, acts as an etch stop during the bottom barrier-less interconnect etch (see below). Suitable materials for capping layer 210 include, but are not limited to, nitride materials such as silicon nitride (SiN), silicon oxynitride (SiON) and/or silicon oxycarbonitride (SiOCN). A process such as CVD, ALD or PVD can be employed to deposit the capping layer 210 onto dielectric 206. According to an exemplary embodiment, the capping layer 210 has a thickness of from about 2 nm to about 5 nm and ranges therebetween.

As shown in FIG. 3, a dielectric 302 is then deposited onto the capping layer 210 over dielectric 206 and metal lines 208a,b,c, etc. For clarity, the terms ‘first’ and ‘second’ may also be used herein when referring to dielectric 206 and dielectric 302, respectively. As provided above, above, suitable materials for dielectric 302 include, but are not limited to, oxide low-κ materials such as SiOx and/or oxide ULK-ILD materials such as pSiCOH. A process such as CVD, ALD, or PVD can be used to deposit the dielectric 302 onto the capping layer 210 over dielectric 206 and metal lines 208a,b,c, etc. Following deposition, dielectric 302 can be planarized using a process such as CMP. According to an exemplary embodiment, dielectric 302 has a thickness of from about 20 nm to about 40 nm and ranges therebetween.

As shown in FIG. 4, standard lithography and etching techniques (see above) are then employed to pattern features 402-408 in dielectric 302. As highlighted above, the features can include trenches, vias (as in features 402, 406 and 408) or a combination thereof (as in feature 404). Namely, as shown in FIG. 4, feature 404 includes a via and a trench on top of the via that is aligned with the via. As highlighted above, when the trench is patterned before the via, it is also referred to as a ‘trench-first’ process. Alternatively, when the via is patterned before the trench, it is referred to as a ‘via-first’ process.

As shown in FIG. 4, features 406 and 408 extend only part way through the dielectric 302. On the other hand, features 402 and 404 are located over the metal lines 208a and 208b, and extend through dielectric 302 and capping layer 210 such that metal lines 208a and 208b are exposed at the bottoms of features 402 and 404, respectively. A directional (anisotropic) etching process such as RIE can be employed to pattern the features 402-408 in dielectric 302. As noted above, capping layer 210 can act as an etch stop during the patterning of features 402-408. For instance, a first RIE step (such as an oxide-selective RIE) can be employed to pattern the features 402-408 in dielectric 302, stopping on the capping layer 210. A second RIE step (such as a nitride-selective RIE) can then be employed to extend features 402 and 404 through the capping layer 210.

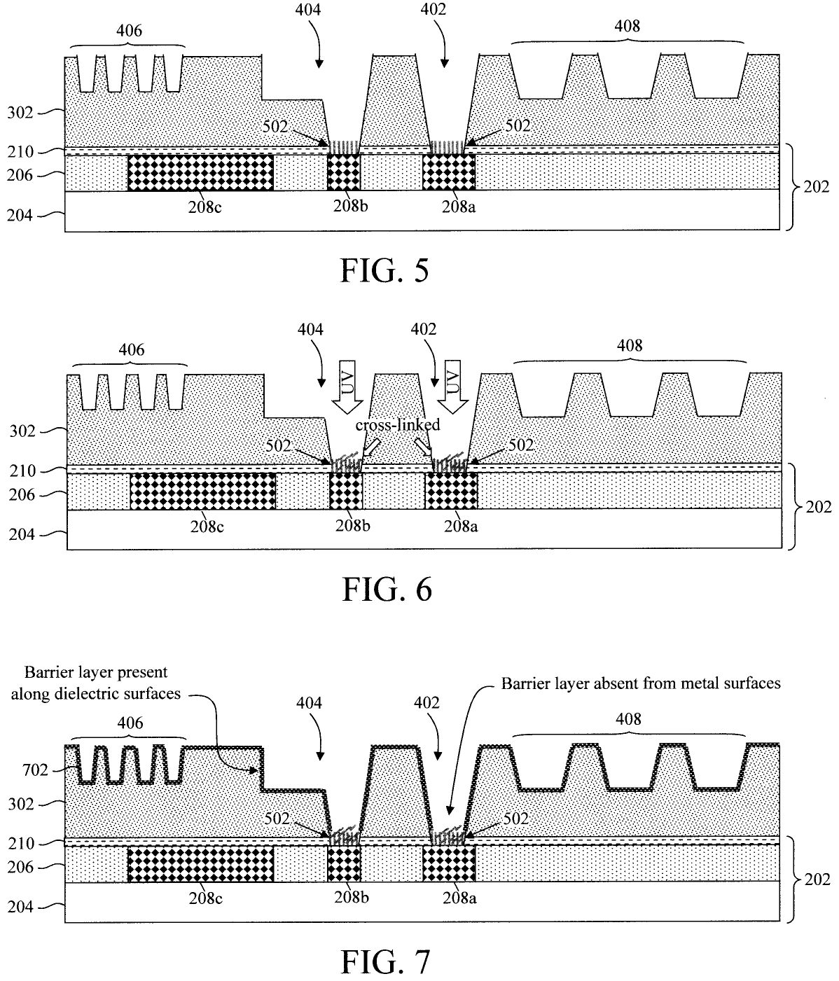

As shown in FIG. 5, a SAM 502 is selectively formed on the surfaces of the metal lines 208a and 208b exposed within features 402 and 404. As highlighted above, the SAM 502 modifies the surface energy properties of the metal lines 208a and 208b to which the SAM 502 is grafted, thereby suppressing chemical deposition of the conformal barrier layer material that will be deposited into the features 402 and 404 onto the metal lines 208a and 208b. As a result, the barrier layer (as-deposited) will be present only on the surfaces of dielectric 302 within the features 402-408. Advantageously, this will permit the interconnects that will be formed within features 402 and 404 to be in direct contact with the metal lines 208a and 208b, respectively. This configuration is what is referred to herein as a ‘bottom barrier-less interconnect.’ Having a bottom barrier-less interconnect greatly reduces the interconnect resistance due to the direct metal-to-metal contact between the interconnects and the metal lines 208a and 208b.

According to an exemplary embodiment, SAM 502 is a photoactive polymer such as dyine-reinforced polynorbornene (PNB). As highlighted above, SAM 502 can be formed on the metal lines 208a and 208b by contacting the metal lines 208a and 208b with a solution of the photoactive polymer. For instance, the solution can be formed by dissolving the dyine-reinforced PNB in a solvent such as 0.1 wt. % 4-methyl-2-pentanol. The device sample can then be immersed in the solution for a duration of from about 5 minutes to about 20 minutes and ranges therebetween, e.g., for about 10 minutes, after which it is removed from the solution and rinsed.

The SAM 502 is then cured. See FIG. 6. According to an exemplary embodiment, the SAM 502 is cured by exposing it to UV light. Exposing the SAM 502 to UV light serves to cross-link the photoactive polymer. The SAM 502, which is present only on the surfaces of metal lines 208a and 208b within features 402 and 404, will suppress chemical deposition of the barrier layer material that is next deposited into the features 402 and 404. Thus, the utility of the intermediate structure shown in FIG. 6 is that this structure would lead to the product described by the present method, and thus a better product in the form of a bottom barrier-less interconnect which greatly reduces the interconnect resistance due to the direct metal-to-metal contact between the interconnects and the metal lines 208a and 208b.

A conformal barrier layer 702 is then deposited into and lining the features 402-408. See FIG. 7. However, due to the presence of the (cured) SAM 502 on the metal lines 208a and 208b, deposition of barrier layer 702 onto metal lines 208a and 208b within features 402 and 404 is suppressed. Thus, as shown in FIG. 7, the barrier layer 702 will be present along the surfaces of dielectric 302, but absent from the surfaces of the metal lines 208a and 208b at the bottoms of features 402 and 404.

As provided above, suitable materials for barrier layer 702 include, but are not limited to, TaN, TiN, TiOx and/or WC. A process such as ALD or PVD can be employed to deposit the barrier layer 702 into and lining the features 402-408. For instance, according to an exemplary embodiment, a thermal ALD process performed at a temperature of from about 250° C. to about 300° C. and ranges therebetween is employed to deposit the barrier layer 702 into the features 402-408. In one exemplary embodiment, barrier layer 702 has a thickness of from about 2 nanometers (nm) to about 5 nm and ranges therebetween.

Although not explicitly shown in the figures, a seed layer can optionally be deposited into the features 402-408 over barrier layer 702 prior to interconnect metal deposition. A seed layer facilitates plating of the metal (see below) into the features 402-408. For instance, by way of example only, when Cu is deposited as the interconnect metal, a Cu-containing seed layer can first be deposited into and lining the features 402-408 over barrier layer 702. This seed layer can include Cu alone, or in combination with one or more other metals such as manganese (Mn), e.g., a CuMn alloy.

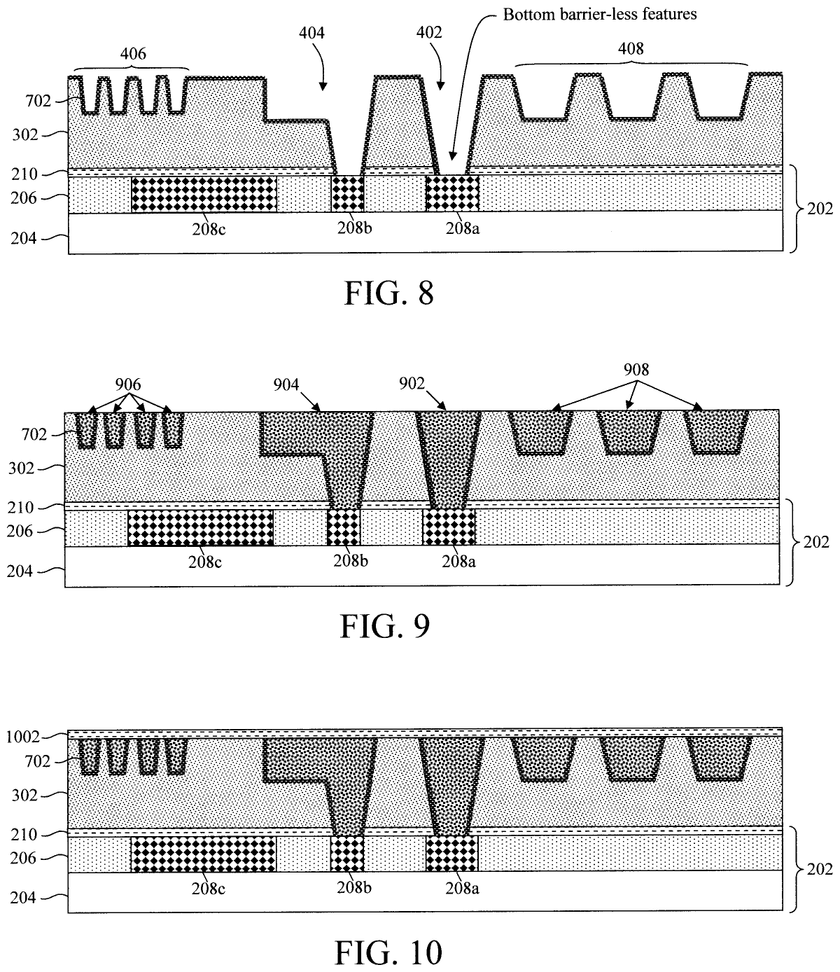

The SAM 502 is next removed from the surface of the metal lines 208a and 208b within features 402 and 404. See FIG. 8. By way of example only, an anisotropic etch process such as RIE or an isotropic etch process such as a wet chemical etch can be employed to remove SAM 502 from features 402 and 404. As shown in FIG. 8, removal of the SAM 502 exposes the ‘barrier-less’ surfaces of the metal lines 208a and 208b, which desirably enable the metal(s) next deposited into the features 402 and 404 to be in direct contact with the metal lines 208a and 208b. As provided above, the absence of the barrier layer 702 at the bottoms of the features 402 and 404 vastly reduces the resistance of the resulting interconnect structure.

A metal or combination of metals is then deposited into the features 402-408 over the barrier layer 702 to form interconnects 902-908 in features 402-408. See FIG. 9. As shown in FIG. 9, due to the barrier-less design at the bottoms of features 402 and 404, there is direct metal-to-metal contact between interconnects 902/904 and metal lines 208a/208b, respectively. As provided above, suitable metals include, but are not limited to, Cu, W, Co and/or Ru. A process such as evaporation, sputtering or electrochemical plating can be employed to deposit the metal(s) into features 402-408. Following deposition, the metal overburden can be removed using a process such as CVD which polishes the metal down to the surface of the dielectric 302. The top surfaces of the dielectric 302 and the interconnects 902-908 are now coplanar as shown in FIG. 9.

Finally, a capping layer 1002 is formed on the dielectric 302 over the interconnects 902-908. See FIG. 10. As provided above, suitable materials for capping layer 1002 include, but are not limited to, nitride materials such as SiN, SiON and/or silicon SiOCN. A process such as CVD, ALD or PVD can be employed to deposit the capping layer 1002 onto dielectric 302. According to an exemplary embodiment, capping layer 1002 has a thickness of from about 2 nm to about 5 nm and ranges therebetween.

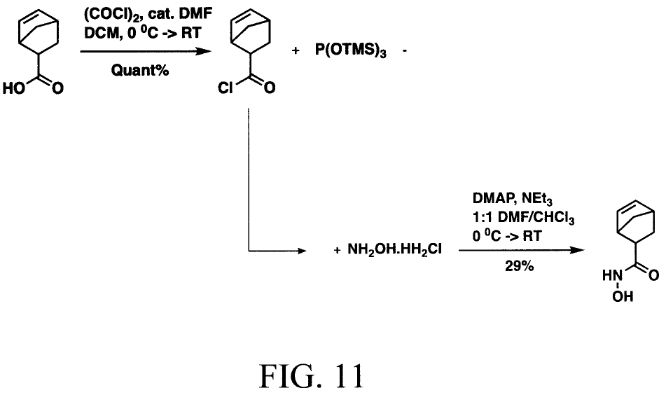

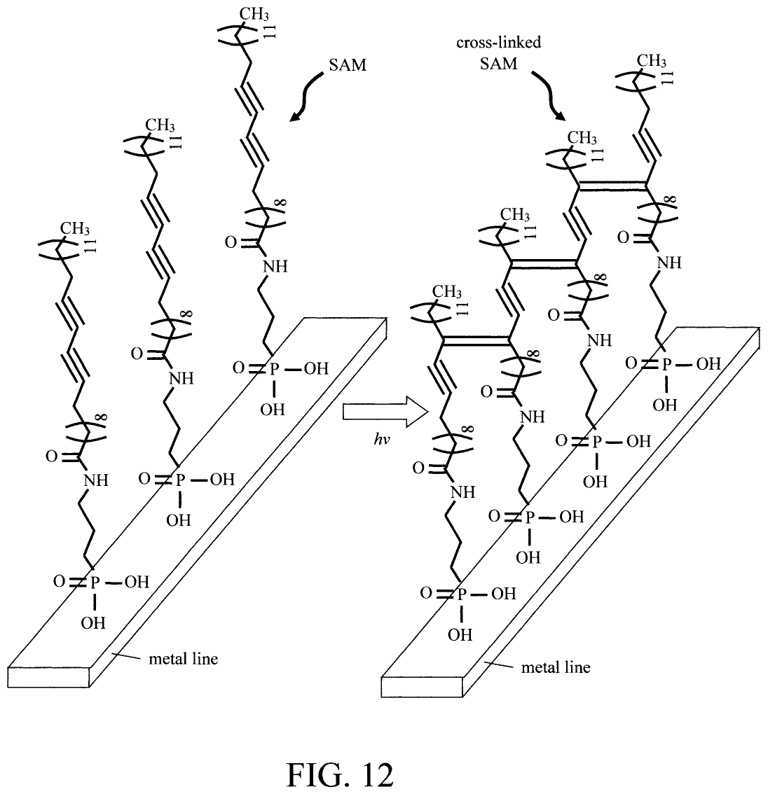

As provided above, the photoactive polymer such as dyine-reinforced polynorbornene (PNB) is configured to have a selectivity for binding to metal surfaces as opposed to dielectric surfaces, thereby enabling the selective formation of the SAM 502 on the metal lines 208a and 208b. See, for example, FIG. 11 which provides an exemplary reaction to functionalize the SAM 502 for preferential binding to metal surfaces. For instance, in one non-limiting example, exo-5-Norbornenecarboxylic acid (1 g, 7.23 mmol) and a catalytic (cat.) amount of dry dimethylformamide (DMF) (one drop) was suspended in dry dichloromethane (DCM) (25 mL) and placed in a flame dried 50 mL round bottomed flask equipped with a magnetic stirrer bar. The mixture was placed under an atmosphere of nitrogen (N₂) and cooled with an ice bath. Oxalyl chloride (COCl)₂ (1.85 g, 14.47 mmol, 2 eq.) was added dropwise to the vigorously stirred solution and allowed to stir for 2 hours at room temperature (RT), whereupon the mixture became a homogenous solution. The solution was then dried under rotary evaporation, re-dissolved in DCM and re-evaporated twice to give the intermediate acid chloride (pale yellow oil). Assuming full conversion, the intermediate was immediately dissolved in 1:1 dry CHCl₃/DMF (25 mL) and cooled with an ice bath under an N₂ atmosphere. 4-Dimethylaminopyridine (DMAP) (9 mg, 0.07 mmol), hydroxylammonium chloride (NH₂OH.HCl) (1 g, 14.46 mmol) and triethylamine (NEt₃) (1.46 g, 14.46 mmol) were added sequentially and the reaction mixture was allowed to slowly warm to room temperature and stirred for another 16 hours. The mixture was quenched with aqueous hydrochloric acid (HCl) (100 mL, 1M) and extracted with trichloromethane (CHCl₃) (3×50 mL). The combined organic fractions were extracted with brine (3×50 mL), dried with sodium sulfate (NaSO₄) and the solvent removed under rotary evaporation to give an oil. The resulting crude oil was further dried overnight under hi-vacuum to dispose of any residual DMF solvent. The pure product hydroxamic acid was obtained as a thick, clear oil that crystallized on standing (3, 325 mg, 29%).

In the example provided above, the SAM 502 of photoactive polymer selectively deposited onto the metal lines 208a and 208b is cured by exposing it to UV light. See, for example, FIG. 12. As shown in FIG. 12, exposing the SAM 502 to UV light serves to cross-link the photoactive polymer.

Although illustrative embodiments of the present invention have been described herein, it is to be understood that the invention is not limited to those precise embodiments, and that various other changes and modifications may be made by one skilled in the art without departing from the scope of the invention.

1. An interconnect structure, comprising:
a dielectric disposed over at least one metal line;
at least one feature present in the dielectric over the at least one metal line;
a barrier layer lining only surfaces of the dielectric within the at least one feature; and
at least one interconnect present in the at least one feature over the barrier layer, wherein the at least one interconnect is in direct contact with the at least one metal line.

2. The interconnect structure of claim 1, wherein the at least one feature is selected from the group consisting of: a trench, a via, or combinations thereof.

3. The interconnect structure of claim 1, wherein the at least one feature comprises a via and a trench on top of the via that is aligned with the via.

4. The interconnect structure of claim 1, wherein the barrier layer comprises a material selected from the group consisting of: tantalum nitride (TaN), titanium nitride (TiN), titanium oxide (TiOx), tungsten carbide (WC), and combinations thereof.

5. The interconnect structure of claim 1, wherein the barrier layer has a thickness of from about 2 nm to about 5 nm and ranges therebetween.

6. The interconnect structure of claim 1, wherein the at least one interconnect comprises a metal selected from the group consisting of: copper (Cu), tungsten (W), cobalt (Co), ruthenium (Ru), and combinations thereof.

7. The interconnect structure of claim 1, further comprising:
a capping layer disposed over the at least one interconnect.

8. A structure, comprising:
a dielectric disposed over at least one metal line;
at least one feature present in the dielectric over the at least one metal line;
a self-assembled monolayer (SAM) disposed only on the at least one metal line within the at least one feature; and
a barrier layer lining only surfaces of the dielectric within the at least one feature.

9. The structure of claim 8, wherein the SAM comprises a photoactive polymer.

10. The structure of claim 9, wherein the photoactive polymer comprises dyine-reinforced polynorbornene (PNB).

11. The structure of claim 8, wherein the SAM is cross-linked.

12. The structure of claim 8, wherein the at least one feature is selected from the group consisting of: a trench, a via, or combinations thereof.

13. A method of forming an interconnect structure, the method comprising the steps of:
depositing a dielectric over at least one metal line;
patterning at least one feature in the dielectric over the at least one metal line;
selectively forming a SAM only on the at least one metal line within the at least one feature;
curing the SAM to cross-link the SAM
depositing a barrier layer into and lining the at least one feature, wherein the SAM suppresses deposition of the barrier layer onto the at least one metal line such that the barrier layer as-deposited is present only on surfaces of the dielectric within the at least one feature;
removing the SAM; and
depositing at least one metal into the at least one feature over the barrier layer to form at least one interconnect in the at least one feature that is in direct contact with the at least one feature.

14. The method of claim 13, wherein the at least one feature is selected from the group consisting of: a trench, a via, or combinations thereof.

15. The method of claim 13, wherein the SAM comprises a photoactive polymer.

16. The method of claim 15, wherein the SAM is cured by exposing the photoactive polymer to ultraviolet (UV) light.

17. The method of claim 15, wherein the photoactive polymer comprises dyine-reinforced polynorbornene (PNB).

18. The method of claim 13, wherein the barrier layer comprises a material selected from the group consisting of: TaN, TiN, TiOx, WC, and combinations thereof.

19. The method of claim 13, wherein the at least one metal is selected from the group consisting of: Cu, W, Co, Ru, and combinations thereof.

20. The method of claim 13, further comprising the step of:
forming a capping layer on the dielectric over the at least one interconnect.
